(19) United States
(12) Patent Application Publication
(10) Pub. No.: US 2015/0042901 A1
(43) Pub. Date: Feb. 12, 2015

(54) Touch Integrated Panel, Electronic Device, and Method of Manufacturing Touch Integrated panel

(71) Applicant: InnoLux Corporation, Miao-Li County (TW)

(72) Inventors: Hui-Min HUANG, Miao-Li County (TW); Huai-Chin TSAI, Miao-Li County (TW); Ching-Hsin WU, Miao-Li County (TW)

(21) Appl. No.: 14/336,100

(22) Filed: Jul. 21, 2014

(30) Foreign Application Priority Data
Aug. 7, 2013 (TW) 102128217

(51) Int. Cl. G06F 3/041; G06F 1/16; H01L 27/12; G02F 1/1333

(52) U.S. Cl. CPC G06F 3/0412; G02F 1/13338; G06F 1/1643; H01L 27/1259; G06F 2203/04103
USPC 349/12; 438/23

(57) ABSTRACT

A touch integrated panel includes a first substrate having a first outer surface and a first inner surface where a thin film transistor array is formed, a second substrate having a second outer surface and a second inner surface, and a liquid crystal layer sandwiched between the first inner surface and the second inner surface, wherein a touch sense pattern for sensing touch operations performed on the panel and a key sense pattern for sensing whether a function key is touched are formed on the first outer surface or the second outer surface.

### CROSS REFERENCE TO RELATED APPLICATIONS

This Application claims priority of Taiwan Patent Application No. 102128217, filed on Aug. 7, 2013, the entirety of which is incorporated by reference herein.

### BACKGROUND OF THE INVENTION

1. Field of the Invention

The present invention relates to a touch integrated panel, an electronic device, and a method of manufacturing a touch integrated panel, and in particular, relates to a touch integrated panel, an electronic device, and a more efficient method of manufacturing a touch integrated panel at a low cost.

2. Description of the Related Art

When manufacturing a touch integrated panel, a technique may be used which directly integrates a touch sensor onto or into an LCD (liquid crystal display) panel. For the conventional technique, a touch panel and an LCD panel are separately manufactured and then assembled. On the other hand, LCD panel manufacturers can utilize the touch integrated panel technique to manufacture display panels with touch functions themselves. The touch integrated panel is thinner and lighter and has better optical performance and touch sensitivity versus the conventional assembled touch panel and LCD panel.

However, when physical or virtual function keys are required for the touch integrated panel, the manufacturing of the touch integrated panel becomes less cost efficient. Accordingly, a touch integrated panel, an electronic device, and a more efficient method of manufacturing a touch integrated panel at a low cost are desired.

### BRIEF SUMMARY OF THE INVENTION

A detailed description is given in the following embodiments with reference to the accompanying drawings.

The invention provides a touch integrated panel including: a first substrate having a first outer surface and a first inner surface wherein a thin film transistor array is formed on the first inner surface, a second substrate having a second outer surface and a second inner surface, and a liquid crystal layer sandwiched between the first inner surface and the second inner surface, wherein a touch sense pattern for sensing touch operations and a key sense pattern for sensing whether at least one function key is touched are formed on the first outer surface or the second outer surface.

In the above touch integrated panel, an edge of the second substrate protrudes with respect to an edge of the first substrate at the same side. Further, the key sense pattern is formed on a protrusion area of the second substrate with respect to the first substrate. In addition, the extended length of the protrusion area of the second substrate with respect to the first substrate is 0.5-10 mm.

The invention also provides an electronic device including: the above touch integrated panel; a backlight arranged at the side of the first outer surface or the second outer surface of the touch integrated panel; and a housing covering the touch integrated panel and the backlight, wherein a function key icon representing the function key is formed at a position of a surface of the housing corresponding to the position of the key sense pattern.

In the above electronic device, light emitted from the backlight passes through the touch integrated panel and the housing to illuminate the function key icon.

The invention also provides a method of manufacturing a touch integrated panel, including: forming a thin film transistor array on a first substrate; providing a second substrate; injecting liquid crystal between a surface of the first substrate where the thin film transistor array is formed and an inner surface of the second substrate, and adhering the first substrate to the second substrate; and forming a touch sense pattern and a key sense pattern on an outer surface of the first substrate which faces away from the second substrate or on an outer surface of the second substrate which faces away from the first substrate.

In the above method, for each touch integrated panel, an edge of the second substrate protrudes with respect to an edge of the first substrate at the same side. Further, the key sense pattern is formed on a protrusion area of the second substrate with respect to the first substrate. In addition, the extended length of the protrusion area of the second substrate with respect to the first substrate is 0.5-10 mm.

According to the touch integrated panel, the electronic device, and the method of manufacturing the touch integrated panel, a flexible printed circuit board (including the LED) is not necessary for manufacturing the function key, which reduces manufacturing costs. The key sense pattern and the touch sense pattern can be formed during the same process, which makes manufacturing more efficient. Also, the portion of remainder material is reserved such that material utilization rate of the glass substrate is increased.

### BRIEF DESCRIPTION OF THE DRAWINGS

The present invention can be more fully understood by reading the subsequent detailed description and examples with references made to the accompanying drawings, wherein:

FIG. 1 is a front view showing a touch electronic device having function keys;

FIG. 2A is a side view showing the touch integrated panel of Embodiment 1;

FIG. 2B is a front view showing the touch integrated panel of Embodiment 1;

FIG. 3A is a side view showing the touch integrated panel of Embodiment 2;

FIG. 3B is a front view showing the touch integrated panel of Embodiment 2;

FIG. 4A is a side view showing the cutting process of the touch integrated panel of Embodiment 1;

FIG. 4B is a side view showing the cutting process of the touch integrated panel of Embodiment 2;

FIG. 5A is a side view showing another cutting process of the touch integrated panel of Embodiment 1;

FIG. 5B is a side view showing another cutting process of the touch integrated panel of Embodiment 2; and

FIG. 6 is a flowchart of manufacturing the touch integrated panel of Embodiment 2.

### DETAILED DESCRIPTION OF THE INVENTION

This description is made for the purpose of illustrating the general principles of the invention and should not be taken in a limiting sense. The scope of the invention is best determined by reference to the appended claims.

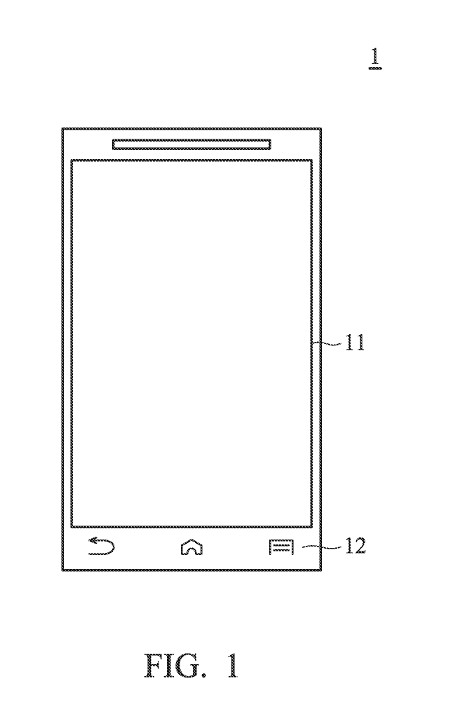

FIG. 1 is a front view showing a touch electronic device having function keys. The touch electronic device having physical function keys, as shown in FIG. 1, comprises a display portion 11 and a key portion 12. The display portion 11 displays images or information for a user and receives touch inputs from the user. The key portion 12 is provided with at least one function key which can be a mechanical key or a touch key. The function key provides a predetermined function, such as back, home, and menu.

To carry out the touch electronic device having function keys as shown in FIG. 1, two touch integrated panels according to embodiments of the invention will be described in the following, and their differences will be discussed.

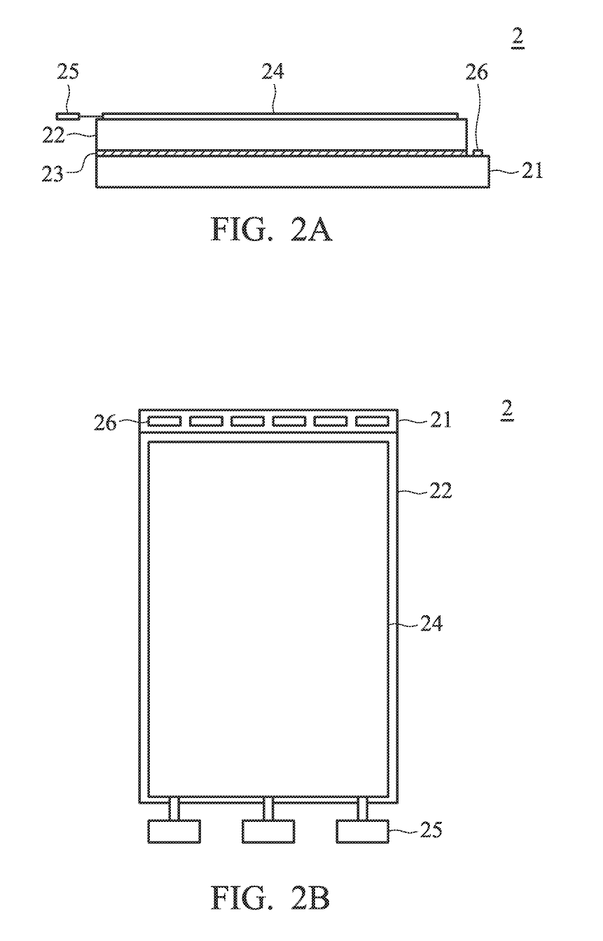

First, the structure of the touch integrated display LCD panel according to Embodiment 1 is described. FIGS. 2A and 2B are a side view and a front view showing the touch integrated panel of Embodiment 1, respectively. When the housing (or the cover glass) of the mobile phone 1 shown in FIG. 1 is removed, the touch integrated panel 2 of Embodiment 1 is seen. As shown in FIGS. 2A and 2B, the touch integrated panel 2 comprises a lower substrate 21, an upper substrate 22, a liquid crystal layer 23, a touch sense pattern 24, a flexible printed circuit board 25 for the function key, and a driving IC 26. A thin film transistor array is formed on a surface of the lower substrate 21 and a color filter is firmed on a surface of the upper substrate 22. The surface of the lower substrate 21 where the thin film transistor array is formed and the surface of the upper substrate 22 where the color filter is formed face each other and sandwich the liquid crystal layer 23 therebetween. In the touch integrated panel 2, the touch sense pattern 24 is directly formed on an outter surface (opposite to the side of the liquid crystal layer 23) of the upper substrate 22 to perform common touch sensor functions. The flexible printed circuit board 25 for the function key is used to sense (or receive) and transmit signals of the function key. The flexible printed circuit board 25 for the function key can be installed with an LED which emits light from the function key to make it easier for the user to identify the position of the function key when the touch electronic device is operated (not standby mode). In addition, in FIGS. 2A and 2B, an edge of the lower substrate 21 protrudes with respect to the upper substrate 22. The driving IC 26 can be formed in the protrusion area by a chip integrated glass (COG) technique.

Note that if the LCD panel is manufactured by a color-filter integrated array (COA) technique, the thin film transistor array and the color filter are formed on a surface of the same substrate. Therefore, the invention is not limited to having the thin film transistor array and the color filter being formed on different substrates. Further, as a modification, a substrate formed with the thin film transistor array can also be used as an upper substrate. Accordingly, as long as the touch sense pattern 24 is formed on the outter surface of the upper substrate 22, the positions where the thin film transistor array and the color filter are formed are not limited. Further, in FIG. 2A, the flexible printed circuit board 25 and the driving circuit 26 are formed at the opposite side of the panel, but their positions are also not limited.

In Embodiment 1, the flexible printed circuit board 25 is connected to a control circuit board (not shown) of the touch sensor via external wirings to transmit the function key signal. However, as a modification, the flexible printed circuit board 25 can be connected to the control circuit board (not shown) of the touch sensor via wirings patterned on the upper substrate 22. The wirings patterned on the upper substrate 22 and the touch sense pattern 24 can be formed during the same process.

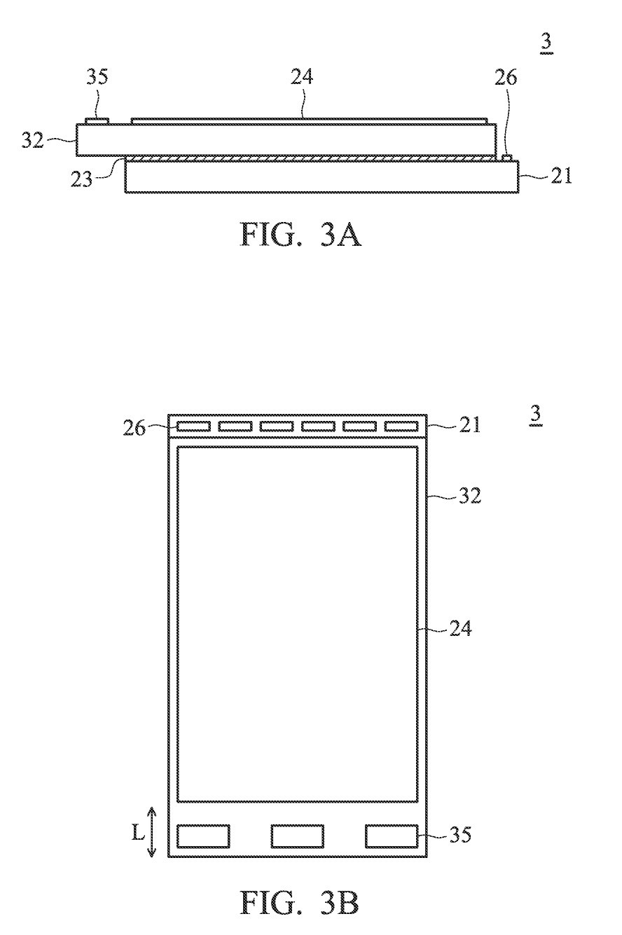

Following, the structure of a touch integrated display LCD panel according to Embodiment 2 is described. FIGS. 3A and 3B are a side view and a front view showing the touch integrated panel of Embodiment 2, respectively. When the housing (or the cover glass) of the mobile phone 1 shown in FIG. 1 is removed, the touch integrated display LCD panel 3 of Embodiment 2 is seen. As shown in FIGS. 3A and 3B, the touch integrated panel 3 comprises a lower substrate 21, an upper substrate 32, a liquid crystal layer 23, a touch sense pattern 24, a key sense pattern 35, and a driving IC 26. The lower substrate 21, liquid crystal layer 23, touch sense pattern 24, and driving IC 26 are the same with those shown in FIGS. 2A and 2B, so the same reference numerals are labeled. The difference between Embodiments 1 and 2 is that the upper substrate 32 of Embodiment 2 extends toward the key portion 12 by a distance L (for example, 0.5-10 mm) This extended distance causes the upper substrate 32 to protrude with respect to the lower substrate 21. Therefore, the key sense pattern 35 for sensing whether the function key is touched can be formed on the protrusion area. In addition, the backlight (not shown) of the touch integrated panel 3 can emit light through the upper substrate 32 and the key sense pattern 35 to make it easier for the user to identify the position of the function key when the touch electronic device is operated (not standby mode).

In this way, in comparison with Embodiment 1, the touch integrated panel of Embodiment 2 has a function key sense pattern directly formed on the upper substrate such that a flexible printed circuit board for the function key is not necessary. The manufacturing cost for the flexible printed circuit board is reduced. Furthermore, because the function key sense pattern and the touch sense pattern can be formed during the same process, the touch integrated panel of Embodiment 2 is more efficient to manufacture.

Note that if the LCD panel is manufactured by a color-filter integrated array (COA) technique, the thin film transistor array and the color filter are formed on a surface of the same substrate. Therefore, the invention is not limited to having the thin film transistor array and the color filter being formed on different substrates. Further, as a modification, a substrate formed with the thin film transistor array can also be used as an upper substrate. Accordingly, as long as the touch sense pattern 24 and the key sense pattern 35 are formed on the outter surface of the upper substrate 32, the positions where the thin film transistor array and the color filter are formed are not limited.

In Embodiment 2, the protrusion area are of the upper substrate 32 with respect to the lower substrate 21 is used for forming the key sense pattern 35. However, as a modification, the key sense pattern 35 can be substituted by a touch key image displayed in the display portion 11. The touch sense pattern 24 is also used to sense whether the function key has been touched.

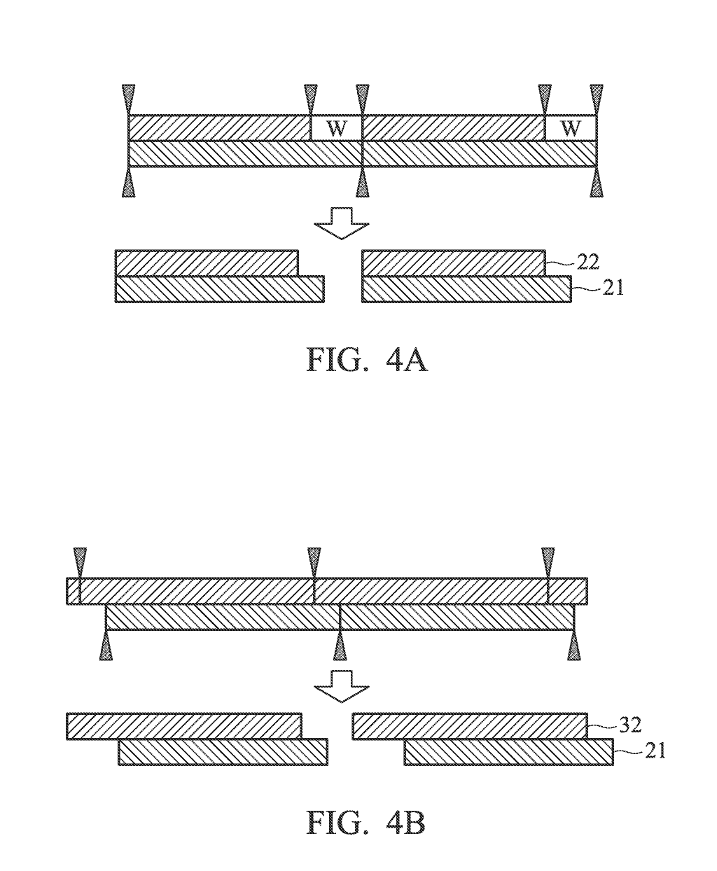

Following, concerning the cutting process of the display panel, the differences between Embodiments 1 and 2 are described. FIG. 4A is a side view showing the cutting process of the touch integrated panel of Embodiment 1. FIG. 4B is a side view showing the cutting process of the touch integrated panel of Embodiment 2. In FIGS. 4A and 4B, an upper substrate and a lower substrate are adhered together and divided into several liquid crystal display panels. The triangles represent the cutting positions. As shown in FIG. 4A, when the touch integrated panel of Embodiment 1 is divided, an unnecessary remainder material W between the adjacent upper substrates 22 should be cut off. On the contrary, as shown in FIG. 4B, when the touch integrated panel of Embodiment 2 is divided, the portion corresponding to the remainder material W of Embodiment 1 doesn't needed to be cut off and the extended length of this portion is further used to form the key sense pattern. In this way, material utilization rate of the glass substrate is increased.

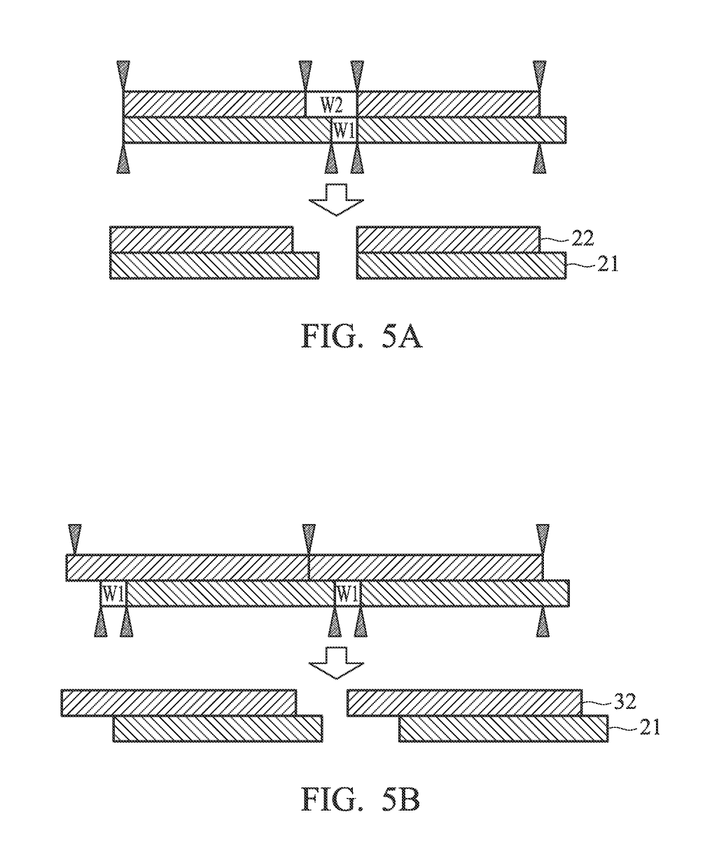

FIG. 5A is a side view showing another cutting process of the touch integrated panel of Embodiment 1. FIG. 5B is a side view showing another cutting process of the touch integrated panel of Embodiment 2. In these two cutting method an interval is reserved between two adjacent lower substrates 21. As shown in FIG. 5A, when the touch integrated panel of Embodiment 1 is divided, an unnecessary remainder material W1 between the adjacent lower substrates 21 and an unnecessary remainder material W2 between the adjacent upper substrates 22 should be cut off. On the contrary, as shown in FIG. 5B, when the touch integrated panel of Embodiment 2 is divided, only the unnecessary remainder material W1 between the adjacent lower substrates 21 should be cut off The portion between the adjacent upper substrates 32 corresponding to the remainder material W2 of Embodiment 1 doesn't needed to be cut off and the extended length of this portion is further used to form the key sense pattern. Similarly, material utilization rate of the glass substrate is increased. Furthermore, cutting the touch integrated panel in this manner can generate a larger portion for forming the key sense pattern than the cutting manner shown in FIG. 4B.

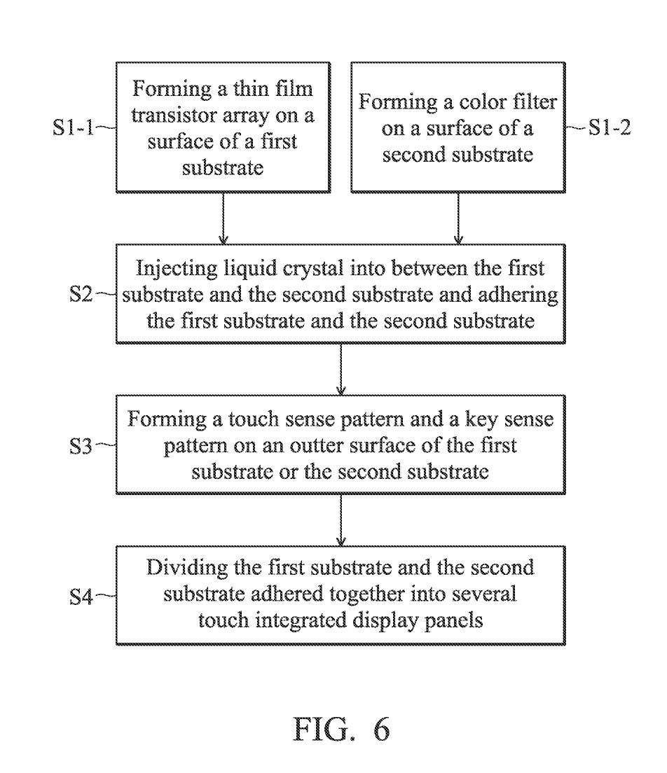

Following, a method of manufacturing the touch integrated panel of Embodiment 2 is described. FIG. 6 is a flowchart of manufacturing the touch integrated panel of Embodiment 2. In FIG. 6, there is no sequence between step S1-1 and step 51-2. Further, these two steps can be processed separately at the same time. At step S1-1, a thin film transistor array is formed on a surface of a first substrate. At step S1-2, a color filter is formed on a surface of a second substrate. After steps S1-1 and S1-2, at step S2 liquid crystal is injected between the surface of the first substrate where the thin film transistor array is formed and the surface of the second substrate where the color filter is formed, and the first substrate and the second substrate are adhered together. Then at step S3, a touch sense pattern and a key sense pattern are formed on an outter surface of the first substrate or the second substrate. Finally, at step S4, the first substrate and the second substrate adhered together are divided into several touch integrated panels. The operation of step S4 is just the operation shown in FIG. 4B or FIG. 5B.

However, the thin film transistor array being formed on the first substrate and the color filter being formed on the second substrate are merely examples. The color filter can be formed on the thin film transistor array of the first substrate rather than the second substrate.

According to the above embodiments, a touch integrated panel, an electronic device, and a more efficient method of manufacturing a touch integrated panel at a low cost is provided. In some embodiments, the flexible printed circuit board (including the LED) is not necessary for manufacturing the function key, which reduces manufacturing costs. The key sense pattern and the touch sense pattern can be formed during the same process, which makes manufacturing more efficient. Also, the portion of remainder material is reserved such that material utilization rate of the glass substrate is increased.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A touch integrated panel, comprising:
a first substrate having a first outer surface and a first inner surface wherein a thin film transistor array is formed on the first inner surface,
a second substrate having a second outer surface and a second inner surface, and
a liquid crystal layer sandwiched between the first inner surface and the second inner surface,
wherein a touch sense pattern for sensing touch operations and a key sense pattern for sensing whether a function key is touched are formed on the first outer surface or the second outer surface.

2. The touch integrated panel as claimed in claim 1, wherein an edge of the second substrate protrudes with respect to an edge of the first substrate at the same side.

3. The touch integrated panel as claimed in claim 2, wherein the key sense pattern is formed on a protrusion area of the second substrate with respect to the first substrate.

4. The touch integrated panel as claimed in claim 3, wherein the extended length of the protrusion area of the second substrate with respect to the first substrate is 0.5-10 mm.

5. An electronic device, comprising:
the touch integrated panel as claimed in claim 1;
a backlight arranged at the side of the first outer surface or the second outer surface of the touch integrated panel; and
a housing covering the touch integrated panel and the backlight,
wherein a function key icon representing the function key is formed at a position of a surface of the housing corresponding to the position of

6. The electronic device as claimed in claim 5, wherein light emitted from the backlight passes through the touch integrated panel and the housing to illuminate the function key icon.

7. A method of manufacturing a touch integrated panel, comprising:
forming a thin film transistor array on a first substrate;
providing a second substrate;
injecting liquid crystal between a surface of the first substrate where the thin film transistor array is formed and an inner surface of the second substrate, and adhering the first substrate to the second substrate; and
forming a touch sense pattern and a key sense pattern on an outer surface of the first substrate which faces away from the second substrate or on an outer surface of the second substrate which faces away from the first substrate.

8. The method as claimed in claim 7, wherein for each touch integrated panel an edge of the second substrate protrudes with respect to an edge of the first substrate at the same side.

9. The method as claimed in claim 8, wherein the key sense pattern is formed on a protrusion area of the second substrate with respect to the first substrate.

10. The method as claimed in claim 9, wherein the extended length of the protrusion area of the second substrate with respect to the first substrate is 0.5-10 mm.
